(19) United States
(12) Patent Application Publication
(10) Pub. No.: US 2014/0137800 A1
(43) Pub. Date: May 22, 2014

(54) DEVICE FOR PRODUCING COMPOUND SEMICONDUCTOR AND WAFER RETAINER

(71) Applicant: Toyoda Gosei Co., Ltd., Kiyosu-shi (JP)

(72) Inventors: Hideki YASUHARA, Kawasaki-shi (JP); Kazutaka YOSHIMURA, Ichihara-shi (JP)

(73) Assignee: TOYODA GOSEI CO., LTD., Kiyosu-shi (JP)

(21) Appl. No.: 14/082,705

(22) Filed: Nov. 18, 2013

(30) Foreign Application Priority Data
Nov. 22, 2012 (JP) 2012-256390

(51) Int. Cl. H01L 21/02

(52) U.S. Cl. CPC H01L 21/0262
USPC 118/725; 118/500

(57) ABSTRACT

Variations in composition in epitaxial growth of a compound semiconductor are suppressed. A wafer retainer that retains a wafer in an MOCVD device includes a carrying member that carries the wafer and a ring-like regulating member that is carried on the carrying member and regulates movement of the wafer carried on the carrying member. On a top surface of the carrying member, a wafer carrying surface for carrying the wafer and a ring carrying surface for carrying the regulating member are provided. The wafer carrying surface is formed to protrude upwardly compared to the ring carrying surface and has a convex shape in which a center portion is higher than a circumferential edge portion, and an arithmetic average roughness Ra of the wafer carrying surface is set at not more than 0.5 μm.

### CROSS REFERENCE TO RELATED APPLICATIONS

This application is based on and claims priority under 35 USC §119 from Japanese Patent Application No. 2012-256390 filed Nov. 22, 2012, incorporated herein by reference in its entirety.

### BACKGROUND

1. Technical Field

The present invention relates to a device for producing a compound semiconductor and a wafer retainer.

2. Related Art

In recent years, various kinds of semiconductor elements, such as an LED (light emitting diode), an FET (field effect transistor) and an HEMT (high electron mobility transistor) using a compound semiconductor, have been widely used.

As a method of growing such a compound semiconductor crystal, a chemical vapor deposition (hereinafter, referred to as a CVD method) is known. In the CVD method, a raw material gas, which is to be a raw material of the compound semiconductor crystal, is supplied into a reaction chamber together with a carrier gas, and subjected to thermal decomposition near a heated substrate in the reaction chamber for epitaxially growing the compound semiconductor crystal on the substrate, and consequently, a compound semiconductor wafer is obtained.

As a conventional technique described in a gazette, there exists a processing device including a locating ring member that places a processed object to become a substrate on a support region of a mounting base and specifies movement of the processed object placed on the support region along a surface of the mounting base including the support region, and a movement control unit that is provided on the locating ring member and the mounting base restricts relative movement along the ring member while permitting relative movement of the locating ring member and the mounting base along a radial direction due to a heat elastic difference of the locating ring member (refer to Japanese Unexamined Patent Application Publication (Translation of PCT Application) No. 2001-525997).

In the CVD method, to perform thermal decomposition of the raw material gas near the substrate, it is common to heat the substrate. At this time, if there was a difference in the substrate temperature between different positions on the substrate (for example, on a circumferential edge side and on a center side), composition of a compound semiconductor layer formed on the substrate varied depending on the position on the substrate in some cases. Here, if variations in composition occur in the compound semiconductor layer formed on the substrate, in the case of the light emitting element such as the LED, light emission wavelength differs depending on the position on the substrate, and in the case of the active element such as the FET and the HEMT, difference occurs in mobility of electros or holes depending on the position on the substrate.

It is an object of the present invention to suppress variations in composition when a compound semiconductor is epitaxially grown.

### SUMMARY

According to an aspect of the present invention, there is provided a device for producing a compound semiconductor that forms a compound semiconductor layer on a wafer by use of a chemical vapor deposition method, the device including: a reaction container that contains the wafer inside thereof; a wafer retainer that is provided in the reaction container and retains the wafer so that a surface of the wafer on which the compound semiconductor layer is formed faces upwardly; a supply portion that supplies a raw material gas which is a raw material of the compound semiconductor layer from an outside to an inside of the reaction container; and a heater portion that heats the wafer via the wafer retainer, wherein the wafer retainer includes: a carrying member that carries the wafer; and a regulating member that is carried on the carrying member and surrounds a circumferential surface of the wafer carried on the carrying member to regulate movement of the wafer, wherein the carrying member includes a first carrying surface that carries the wafer and a second carrying surface that is provided around the first carrying surface and carries the regulating member, and the first carrying surface is formed to protrude compared to the second carrying surface and has a surface shape in a convex state in which a center side is higher than a circumferential edge side, and an arithmetic average roughness Ra of the first carrying surface is not more than 0.5 μm.

In such a device for producing a compound semiconductor, a support body that is rotatably provided in the reaction container and supports the wafer retainer rotatably is further included, wherein the supply portion supplies the raw material gas from above or a lateral side of the support body.

Moreover, the heater portion heats the wafer in a range from not less than 700° C. to not more than 1200° C.

From another viewpoint, according to another aspect of the present invention, there is provided a wafer retainer being used in a device for producing a compound semiconductor that forms a compound semiconductor layer on a wafer by use of a chemical vapor deposition method and retaining the wafer, the wafer retainer including: a carrying member that carries the wafer; and a regulating member that is carried on the carrying member and surrounds a circumferential surface of the wafer carried on the carrying member to regulate movement of the wafer, wherein the carrying member includes a first carrying surface that carries the wafer and a second carrying surface that is provided around the first carrying surface and carries the regulating member, and the first carrying surface is formed to protrude compared to the second carrying surface and has a surface shape in a convex state in which a center side is higher than a circumferential edge side, and an arithmetic average roughness Ra of the first carrying surface is not more than 0.5 μm.

In such a wafer retainer, the chemical vapor deposition method is a metal organic chemical vapor deposition method, and the compound semiconductor layer is a group III nitride semiconductor layer.

Moreover, the wafer is configured with a substrate on which a compound semiconductor layer is formed in advance.

Further, the carrying member is configured by forming a coating layer composed of SiC on a surface of a base composed of carbon, and the regulating member is composed of quartz.

According to the present invention, it is possible to suppress variations in composition when a compound semiconductor is epitaxially grown.

### BRIEF DESCRIPTION OF THE DRAWINGS

An exemplary embodiment of the present invention will be described in detail based on the following figures, wherein:

FIG. 1 is a schematic view showing an example of a cross-sectional configuration of an MOCVD (metal organic chemical vapor deposition) device;

FIG. 2 is a II-II cross-sectional view of the MOCVD device shown in FIG. 1;

FIGS. 3A and 3B are diagrams for illustrating an example of a configuration of a wafer retainer used to retain a wafer in the MOCVD device;

FIG. 4 is an exploded perspective view of the wafer retainer;

FIGS. 5A and 5B are diagrams for illustrating a configuration of a carrying member in the wafer retainer;

FIGS. 6A and 6B are diagrams for illustrating a configuration of a regulating member in the wafer retainer;

FIGS. 7A to 7C are vertical cross-sectional views of the wafer retainer;

FIG. 8 is a diagram for illustrating an example of a configuration of a carrying surface in the carrying member;

FIG. 9 is a cross-sectional view showing an example of a configuration of a laminated semiconductor wafer produced by use of the MOCVD device; and

FIG. 10A to 10D are diagrams showing relation between a three-dimensional shape of the wafer carrying surface in the wafer retainer and a PL wavelength distribution in the obtained laminated semiconductor wafer in each of Example 1 and Comparative Examples 1 to 3.

### DETAILED DESCRIPTION

Hereinafter, an exemplary embodiment according to the present invention will be described in detail with reference to accompanying drawings.

### <Configuration of MOCVD Device>

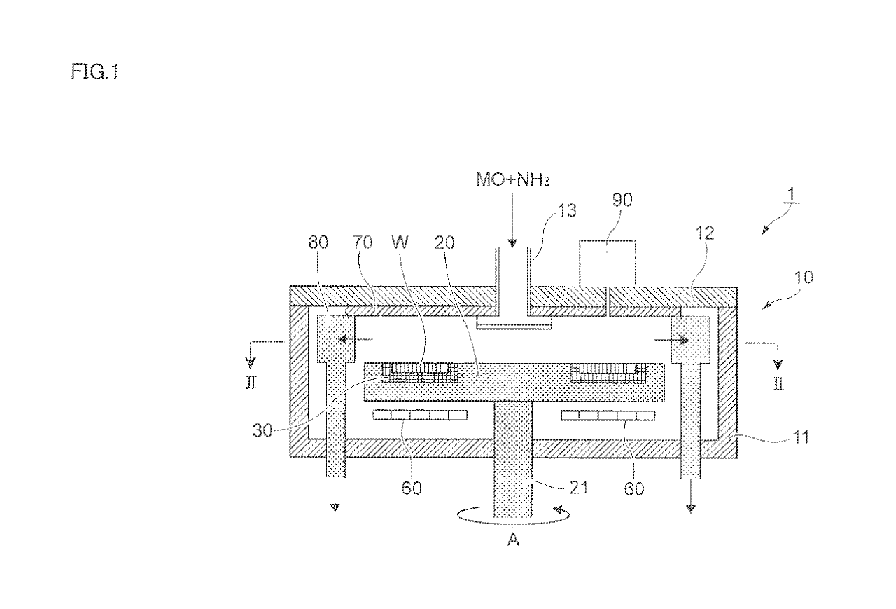

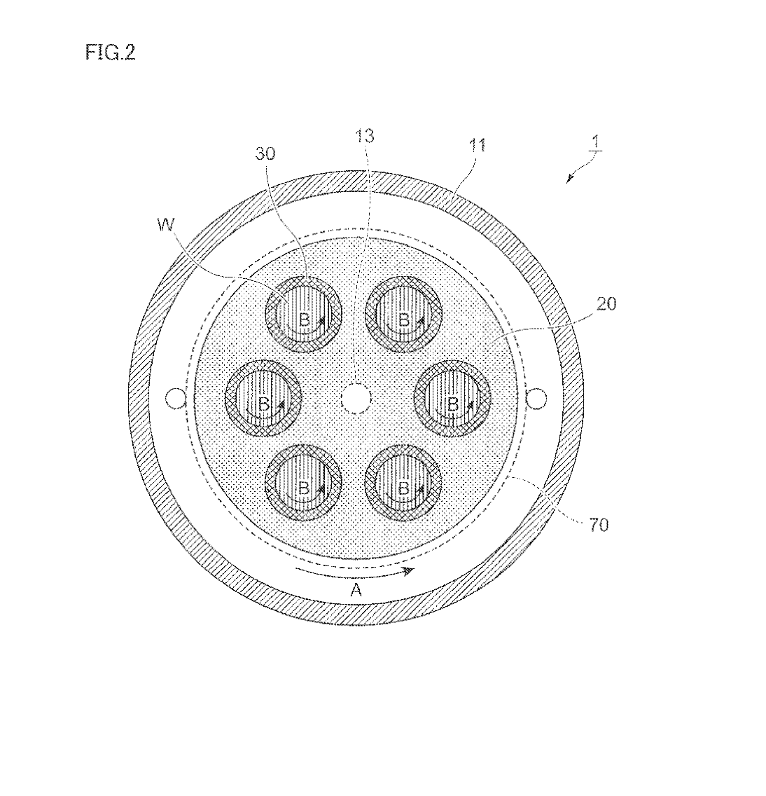

FIG. 1 is a diagram showing a cross-sectional configuration of an MOCVD device 1 that uses MOCVD (metal organic vapor deposition), which is one of the chemical vapor deposition methods. FIG. 2 is a II-II cross-sectional view of the MOCVD device 1 shown in FIG. 1.

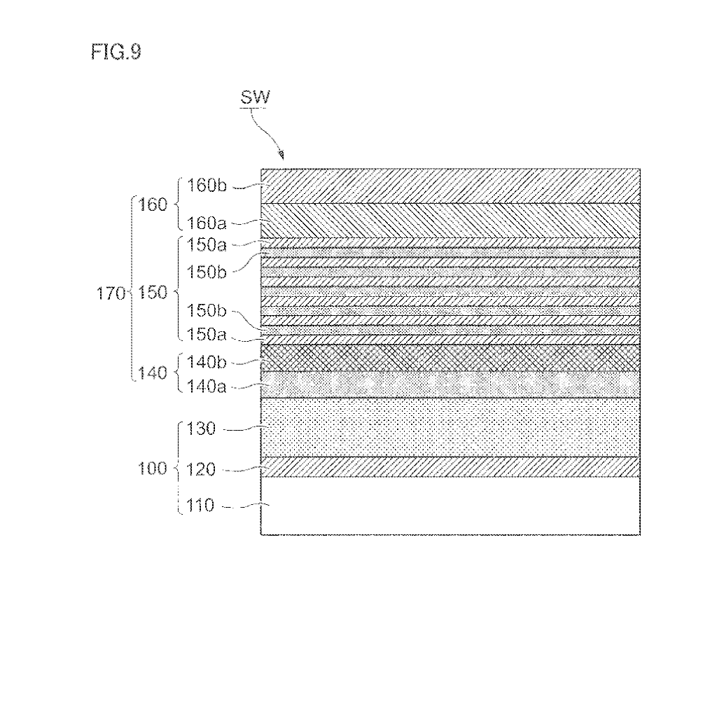

The MOCVD device 1 has a configuration in which a wafer W (configured with a substrate 110 (refer to FIG. 9) or a lamination substrate 100 configured by forming at least one compound semiconductor layer on the substrate 110 (refer to FIG. 9), which will be described later) is arranged so that a crystal growth surface thereof faces upward, and a raw material gas, which will be a raw material of a compound semiconductor crystal to be epitaxially grown, is supplied to a top surface side of the wafer W from above or a lateral side of the wafer W.

The MOCVD device 1 includes a reaction container 10 in which a reaction chamber is formed and a support body 20 that is arranged in the reaction chamber of the reaction container 10 and supports a wafer retainer 30 to be described later.

Of these, the reaction container 10 includes a container portion 11 that has a cylindrical form and aperture opening upwardly, and contains the support body 20 therein and a lid portion 12 having a disc shape and attached to an upper portion of the container portion 11.

Here, the container portion 11 and the lid portion 12 are configured with metal such as a stainless steel. In addition, the lid portion 12 is attached to the container portion 11 to be openable and closable, and in the case of closing the container portion 11, forms the reaction chamber together with the container portion 11. It should be noted that a not shown sealing member such as an O-ring is attached to a location where the container portion 11 and the lid portion 12 face each other.

Moreover, at a center part of the lid portion 12, a through hole for supplying a raw material gas from a gas supply mechanism (not shown) provided outside to the inside of the reaction chamber is formed. A supply tube 13, as a specific example of a supply portion, is connected to the through hole. Further, at a position deviated from the center part of the lid portion 12, a through hole for observing the inside of the reaction chamber is also formed.

On the other hand, in a bottom surface of the container portion 11, plural exhaust tubes for ejecting the raw material gas supplied into the reaction chamber to the outside of the reaction chamber are formed through the bottom surface. At a center part of the bottom surface of the container portion 11, a through hole (not shown) for passing a shaft 21 to be described later is formed.

Here, the raw material gas used in the MOCVD device 1 will be described.

In the exemplary embodiment, on the wafer W (the substrate 110 or the lamination substrate 100), a group III nitride semiconductor layer, as a specific example of a compound semiconductor layer, is formed by use of the MOCVD device 1. Consequently, as the raw materials, organic metal containing a group III element and ammonia NH₃ containing nitride are used. However, since the organic metal is mainly a liquid feedstock, bubbling is performed on the organic metal in a liquid state with nitride N₂ and hydrogen H₂, and a metal-organic gas MO generated by mixing the obtained nitride N₂, hydrogen H₂ and the organic metal is supplied as the raw material gas. In the exemplary embodiment, the metal-organic gas MO and ammonia NH₃ are supplied via the supply tube 13. Moreover, a carrier gas (for example, hydrogen H₂) is supplied from the supply tube 13.

It should be noted that, as the organic metal, for example, a group III compound containing Ga, such as trimethyl gallium (TMG) or triethyl gallium (TEG); for example, a group III compound containing Al, such as trimethyl aluminum (TMA) or triethyl aluminum (TEA); and, for example, a group III compound containing In, such as trimethyl indium (TMI) or triethyl indium are provided. Moreover, as an n-type dopant, monosilane (SiH₄) and disilane (Si₂H₆) can be used as Si raw materials; or germane gas (GeH₄), tetramethyl germanium ((CH₃)₄Ge) and tetraethyl germanium ((C₂H₅)₄Ge) can be used as the Ge raw material. On the other hand, as a raw material of a p-type dopant, for example, bis(cyclopentadienyl)magnesium (Cp₂Mg) or bis(ethylcyclopentadienyl)magnesium (EtCp₂Mg) can be used as the Mg raw material. Further, in place of ammonia, hydrazine (N₂H₄) can also be used. It should be noted that, other than the above-described metal-organic gas MO, a configuration containing other group III element is available, and it is possible to contain a dopant such as Ge, Si, Mg, Ca, Zn and Be as necessary. Further, there are some cases where not only the elements which are intentionally added but also impurities which are inevitably contained depending on the layer-forming conditions and the like, or a very small quantity of impurities which are contained in a raw material and a material of a reactor are contained.

The support body 20 has a disc shape, and is placed in the container portion 11 so that one surface, namely, the front surface thereof faces upward and the other surface, namely, the back surface faces downward. The support body 20 is configured with a base material formed of carbon (C) and a coating by SiC applied to the outside thereof. Here, on the front surface side of the support body 20, six recessed portions each of which has a circular shape are formed at same intervals in the circumferential direction. On the other hand, on the back surface side of the support body 20, a shaft 21 made of metal is attached downwardly from the center part thereof, and the shaft 21 protrudes to the outside of the reaction container 10 via the through hole provided at the center part of the bottom surface of the container portion 11. Then, the support body 20 is configured to rotate in the direction of arrow A in FIGS. 1 and 2 by applying a driving force to the shaft 21 from the outside of the reaction container 10.

It should be noted that, inside the support body 20, a through hole (not shown) for supplying nitride N₂ toward the bottom surfaces of the six recessed portions provided in the support body 20 is formed. Here, setting changes in the method for supplying nitride N₂ toward the bottom surfaces of the six recessed portions provided in the support body 20 may be appropriately carried out.

Moreover, in each of the six recessed portions provided on the front surface of the support body 20, the wafer retainer 30 having a circular shape is attached. In each of these wafer retainers 30, a circular-shaped recessed portion is formed on a surface facing upward, and in each recessed portion, the wafer W is attached. It should be noted that a gap is formed between the recessed portion provided in the support body 20 and the wafer retainer 30, and these six wafer retainers 30 are detachably attached to the support body 20.

Here, the wafer W is retained at the recessed portion of the wafer retainer 30 so that a crystal growth surface thereof, namely, a surface on which the crystal is to be grown is exposed to the outside. It should be noted that the wafer W is detachably attached to the wafer retainer 30. Each wafer retainer 30 is configured to rotate in the direction of arrow B in FIG. 2 by a flow of nitride N₂ supplied via the above-described not-shown through hole while each being in a state of retaining the wafer W. It should be noted that the specific structure of the wafer retainer 30 will be described later.

Moreover, between the back surface side of the support body 20 and the bottom surface of the container portion 11 of the MOCVD device 1, a heater portion 60 is provided to heat the wafer W through the support body 20 and the wafer retainer 30. The heater portion 60 has a ring shape in which a hole for passing the shaft 21 is formed, and a coil is contained inside thereof. It should be noted that the heater portion 60 performs electromagnetic induction heating on the carbon constituting the support body 20 by supply of a current to the coil.

Further, below the lid portion 12 and above the support body 20 of the MOCVD device 1, a protecting member 70 that protects the lid portion 12 by preventing a product produced by reaction of the raw material gas supplied to the reaction chamber from attaching to and depositing on an inner wall of the lid portion 12 is provided. Here, the protecting member 70 has a circular shape, and similar to the lid portion 12, a through hole for supplying the raw material gas from the outside to the inside of the reaction chamber is formed at the center part thereof. Moreover, similar to the lid portion 12, also, a through hole for observing the inside of the reaction chamber from the outside is formed in the protecting member 70.

The protecting member 70 is attached to the lid portion 12 by a not shown attaching member. It should be noted that the attaching member is detachably attached to the lid portion 12, and accompanied thereto, it is also possible to attach and detach the protecting member 70 to and from the lid portion 12. Moreover, the protecting member 70 is configured to be fastened by being attached to the lid portion 12 through the attaching member.

It should be noted that, as indicated by a broken line in FIG. 2, the protecting member 70 is arranged to cover an entire surface of the support body 20 as viewed from above in a state of closing the lid portion 12 with respect to the container portion 11. Accordingly, the six wafers W retained by the support body 20 through the wafer retainers 30 are positioned below the protecting member 70.

Moreover, between the support body 20 and the protecting member 70 of the MOCVD device 1, an exhaust member 80 that guides the raw material gas or the like that has been supplied to the reaction chamber and used for epitaxial growth of crystal toward the exhaust tubes provided on the bottom surface of the container portion 11 is attached. The exhaust member 80 has a ring-like shape. An inner wall of the exhaust member 80 is positioned at the outer side of the six recessed portions provided in the support body 20. On the inner wall of the exhaust member 80, plural through holes (not shown) for ejecting the raw material gas or the like after using to the outside are formed. The exhaust member 80 is configured not to hinder the rotation of the support body 20 at a location facing the peripheral end side of the outer circumferential portion of the support body 20. Moreover, in FIG. 2, illustration of the exhaust member 80 is omitted.

Then, above the through hole (not shown) provided in the lid portion 12 of the MOCVD device 1, a monitoring device 90 is attached. Via each of the through holes provided to the lid portion 12 and the protecting member 70, the monitoring device 90 monitors the status inside the reaction chamber, and more specifically, monitors the status of crystal epitaxially growing on the wafer W retained by the support body 20 via the wafer retainer 30 and the status of warping in the wafer W or the like. It should be noted that, for preventing the raw material gas or the like from flowing into the monitoring device 90 via these through holes, for example, a purge gas such as nitride N₂ is supplied from the monitoring device 90 toward the reaction chamber.

### <Configuration of Wafer Retainer>

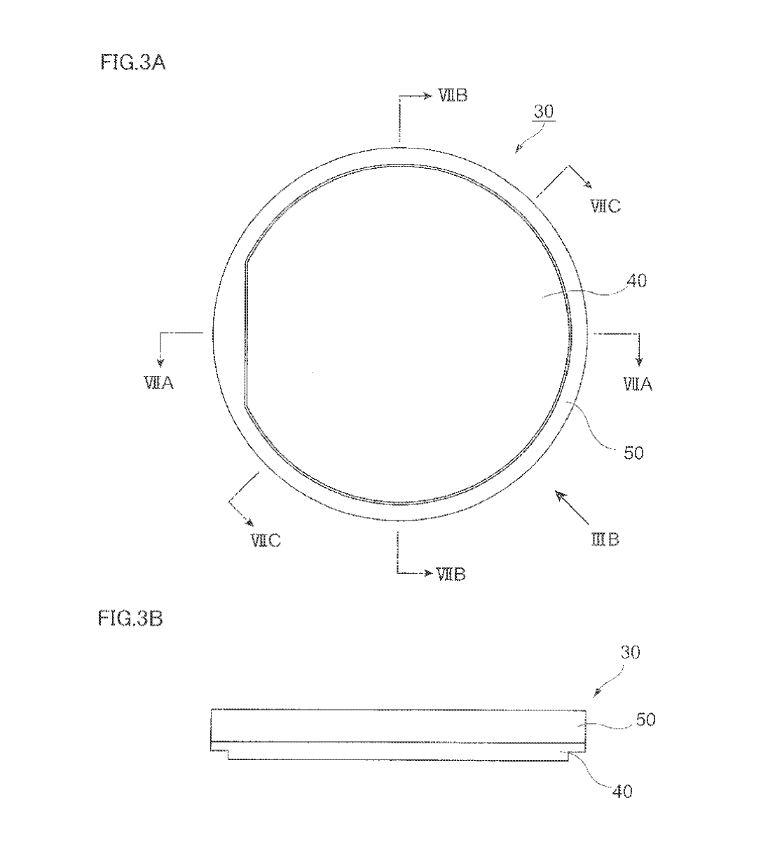

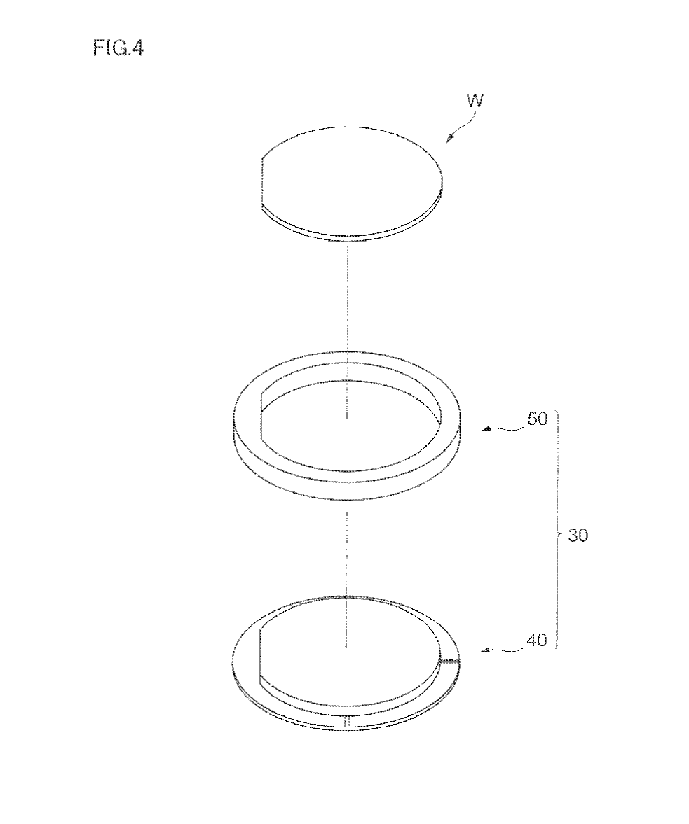

FIGS. 3A and 3B are diagrams showing an example of a configuration of the wafer retainer 30 used to retain the wafer W in the MOCVD device 1 shown in FIG. 1 or the like. Here, FIG. 3A is a top view of the wafer retainer 30 as viewed from a side on which the wafer W is retained, and FIG. 3B is a side view of the wafer retainer 30 shown in FIG. 3A as viewed from the IIIB direction. Moreover, FIG. 4 is an exploded perspective view of the wafer retainer 30 shown in FIGS. 3A and 3B. However, in FIG. 4, the wafer W retained by the wafer retainer 30 is shown together.

The wafer retainer 30 in the exemplary embodiment includes a carrying member 40 for carrying the wafer W and a regulating member 50 that is attached to the top surface side of the carrying member to regulate movement of the wafer W carried on the carrying member 40. Of these, the carrying member 40 has a disk shape and the regulating member 50 has a ring-like shape. In the wafer retainer 30 of the exemplary embodiment, the regulating member 50 is detachably attached to the carrying member 40.

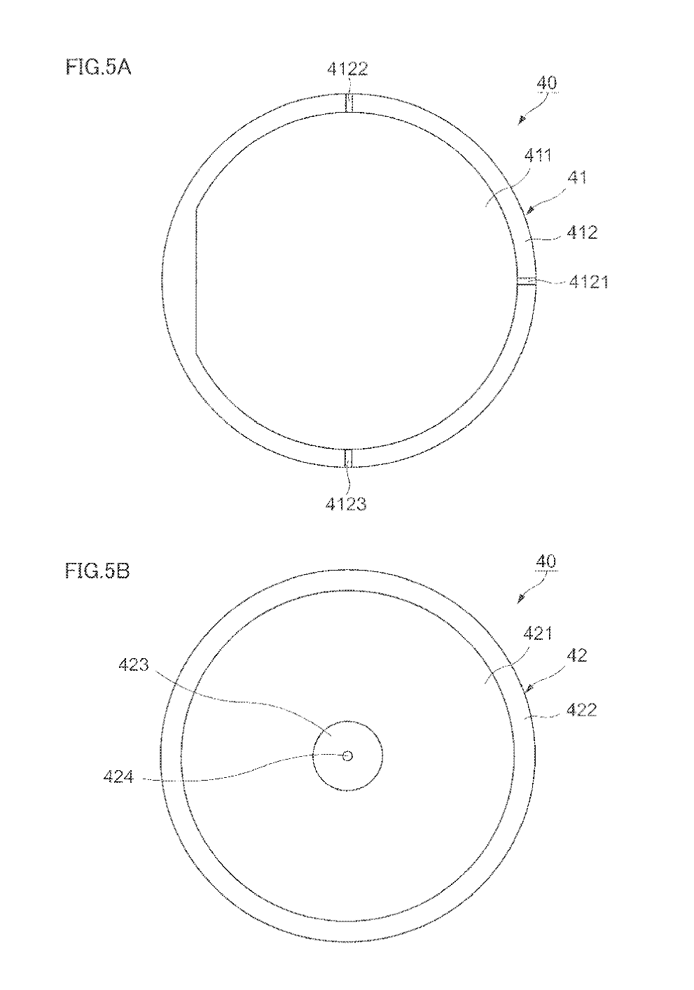

FIGS. 5A and 5B are diagrams for illustrating a configuration of the carrying member 40 in the wafer retainer 30. Here, FIG. 5A is a diagram for illustrating, of the carrying member 40, a configuration of a top surface 41 on which the regulating member 50 and the wafer W are carried, and FIG. 5B is a diagram for illustrating, of the carrying member 40, a configuration of a bottom surface 42 to be placed on the support body 20. The carrying member 40 is, similar to the above-described support body 20 (refer to FIG. 1), configured with a base formed of carbon (C) and a coating by SiC applied to the outside thereof.

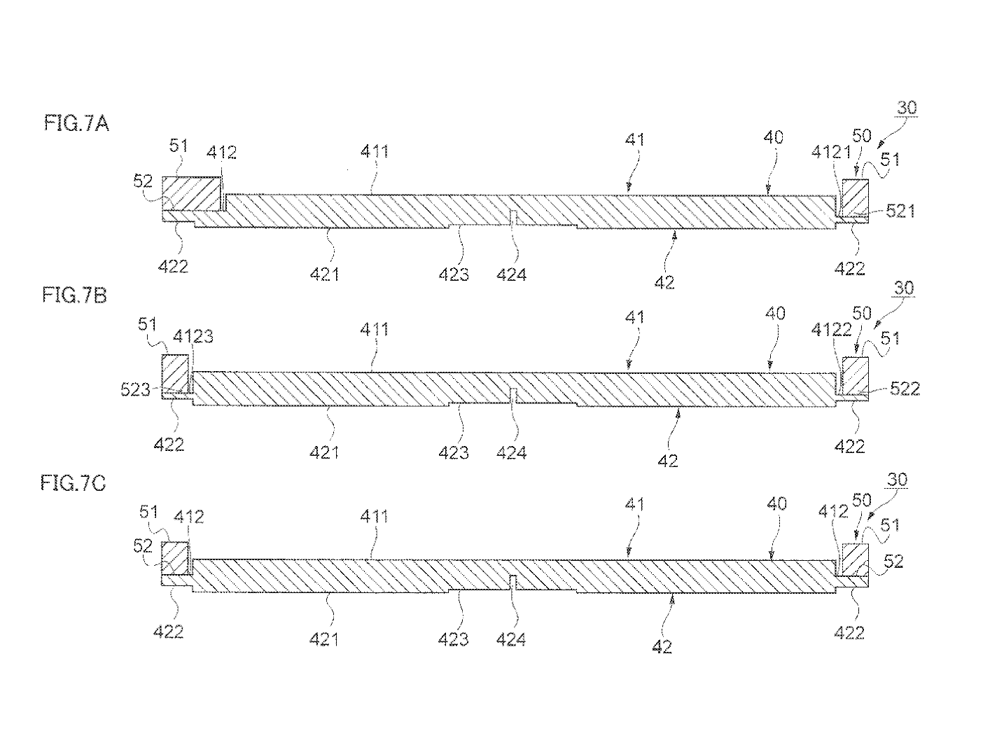

First, as shown in FIG. 5A, the top surface 41 of the carrying member 40 has a wafer carrying surface 411 for carrying the wafer W and a ring carrying surface 412 that is provided to protrude outwardly from a circumferential edge of the wafer carrying surface 411 for carrying the ring-like regulating member 50. Here, in the top surface 41 shown in FIG. 5A, the wafer carrying surface 411, as a specific example of a first carrying surface, protrudes toward the front side in the figure compared to the ring carrying surface 412, as a specific example of a second carrying surface (also refer to FIGS. 7A to 7C, which will be described later).

Moreover, an outer shape of the ring carrying surface 412 indicates a circular shape. On the other hand, an outer shape of the wafer carrying surface 411 basically indicates a circular shape also; however, to follow the shape of the wafer W to be carried thereon, the outer shape has a linear cutout corresponding to a position of forming an orientation flat in the wafer W. It should be noted that, on the top surface 41, the wafer carrying surface 411 and the ring carrying surface 412 are arranged concentrically.

Further, on the ring carrying surface 412, a first groove portion 4121, a second groove portion 4122 and a third groove portion 4123, which are recessed toward the depth side in the figure, are radially formed at intervals of 90°. It should be noted that, in this specific example, the second groove portion 4122 and the third groove portion 4123 face each other across the wafer carrying surface 411, and the first groove portion 4121 and the linear cutout corresponding to the above-described orientation flat face each other across the wafer carrying surface 411.

Next, as shown in FIG. 5B, the bottom surface 42 of the carrying member 40 includes: a ring-like carried surface 421 to be carried on the support body 20; an outer facing surface 422 that is provided to protrude outwardly from an outer circumferential edge of the carried surface 421 to face the support body 20 with a predetermined space when being carried on the support body 20; an inner facing surface 423 that is provided inside an inner circumferential edge of the carried surface 421 to face the support body 20 with a predetermined space when being carried on the support body 20; and a center recessed portion 424 provided at the center of the inner facing surface 423. Here, in the bottom surface 42 shown in FIG. 5B, the carried surface 421 protrudes toward the front side in the figure compared to the outer facing surface 422, the inner facing surface 423 and the center recessed portion 424 (also refer to FIGS. 7A to 7C, which will be described later).

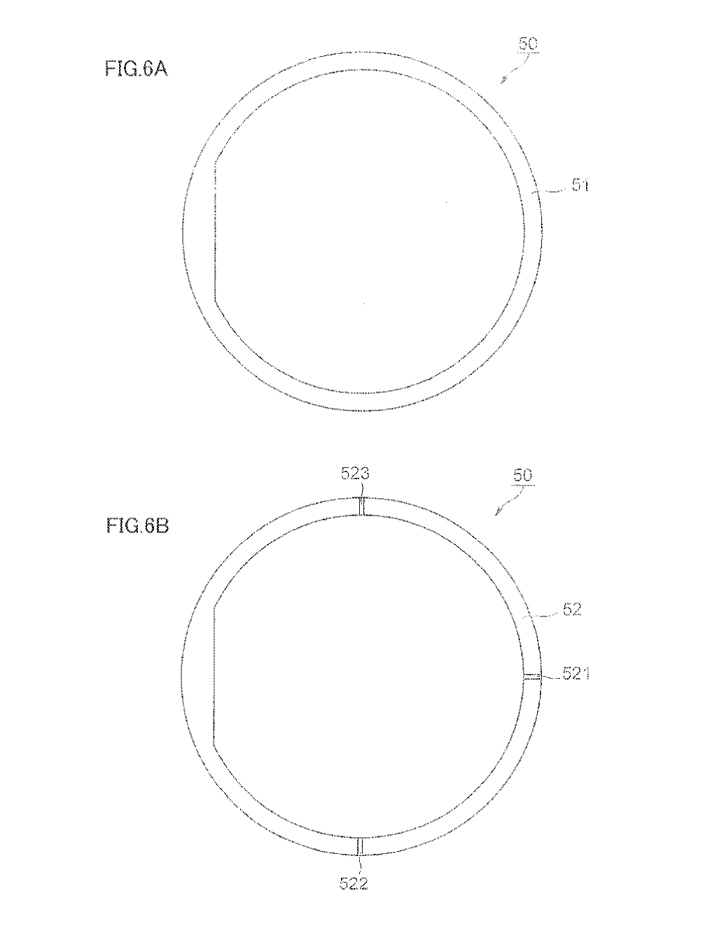

FIGS. 6A and 6B are diagrams for illustrating a configuration of the regulating member 50 in the wafer retainer 30. Here, FIG. 6A is a diagram for illustrating, of the regulating member 50, a structure of an exposed surface 51, which is exposed upwardly when constituting the wafer retainer 30 together with the carrying member 40, and FIG. 6B is a diagram for illustrating, of the regulating member 50, a structure of a contact surface 52, which is brought into contact with the ring carrying surface 412 of the carrying member 40 when constituting the wafer retainer 30 together with the carrying member 40. The regulating member 50 is composed of a material different from that of the above-described carrying member 40, for example, quartz.

The outer shape of the regulating member 50 in the exemplary embodiment basically indicates a ring-like shape. However, though the outside of the regulating member 50 indicates a circular shape, the inside thereof has a linear portion corresponding to the position of forming the orientation flat in the wafer W.

First, as shown in FIG. 6A, the exposed surface 51 of the regulating member 50 is configured with a flat surface.

In contrast, as shown in FIG. 6B, on the contact surface 52 of the regulating member 50, a first furrow portion 521, a second furrow portion 522 and a third furrow portion 523, which protrude toward the front side in the figure, are radially formed at intervals of 90°. It should be noted that, in this specific example, the second furrow portion 522 and the third furrow portion 523 face each other across a space within the ring, and the first furrow portion 521 and the linear portion corresponding to the above-described orientation flat face each other across the space within the ring.

FIGS. 7A to 7C are vertical cross-sectional views of the wafer retainer 30 shown in FIGS. 3A and 3B, which is configured by combining the carrying member 40 shown in FIGS. 5A and 5B and the regulating member 50 shown in FIGS. 6A and 6B. Here, FIG. 7A shows a VIIA-VIIA cross-section in FIG. 3A, FIG. 7B shows a VIIB-VIIB cross-section in FIG. 3A, and FIG. 7C shows a VIIC-VIIC cross section in FIG. 3A.

In the exemplary embodiment, the wafer retainer 30 is configured by attaching the contact surface 52 of the regulating member 50 to be in contact with the ring carrying surface 412 in the top surface 41 of the carrying member 40. Here, in the exemplary embodiment, an inner diameter of the regulating member 50 is set slightly larger (the order of 1 mm) than an outer diameter of the ring carrying surface 412 in the carrying member 40.

Then, in the wafer retainer 30, attachment (fitting) of the regulating member 50 to the carrying member 40 is carried out so that the position in the carrying member 40 corresponding to the orientation flat coincides with the position in the regulating member 50 corresponding to the orientation flat. At this time, for example, as shown in FIG. 7A, the first furrow portion 521 provided on the contact surface 52 of the regulating member 50 is fitted into the first groove portion 4121 provided on the ring carrying surface 412 in the top surface 41 of the carrying member 40. Moreover, for example, as shown in FIG. 7B, the second furrow portion 522 provided on the contact surface 52 of the regulating member 50 is fitted into the second groove portion 4122 provided on the ring carrying surface 412 of the carrying member 40, and the third furrow portion 523 provided on the contact surface 52 of the regulating member 50 is fitted into the third groove portion 4123 provided on the ring carrying surface 412 of the carrying member 40. Consequently, in the wafer retainer 30 of the exemplary embodiment, backlash of the regulating member 50 against the carrying member 40 is suppressed.

Moreover, in the exemplary embodiment, the height of the regulating member 50 (a distance between the exposed surface 51 and the contact surface 52) is set larger than a difference in height between the wafer carrying surface 411 and the ring carrying surface 412 in the top surface 41 of the carrying member 40. Accordingly, in the wafer retainer 30, around the wafer carrying surface 411 in the carrying member 40, a wall configured with an inner wall of the regulating member 50 is formed.

Consequently, in the wafer retainer 30, when the wafer W is carried on the wafer carrying surface 411 of the carrying member 40, the circumferential edge of the wafer W is surrounded by the inner wall of the regulating member 50, to thereby regulate movement of the wafer W (more specifically, movement in the horizontal direction) with respect to the wafer retainer 30.

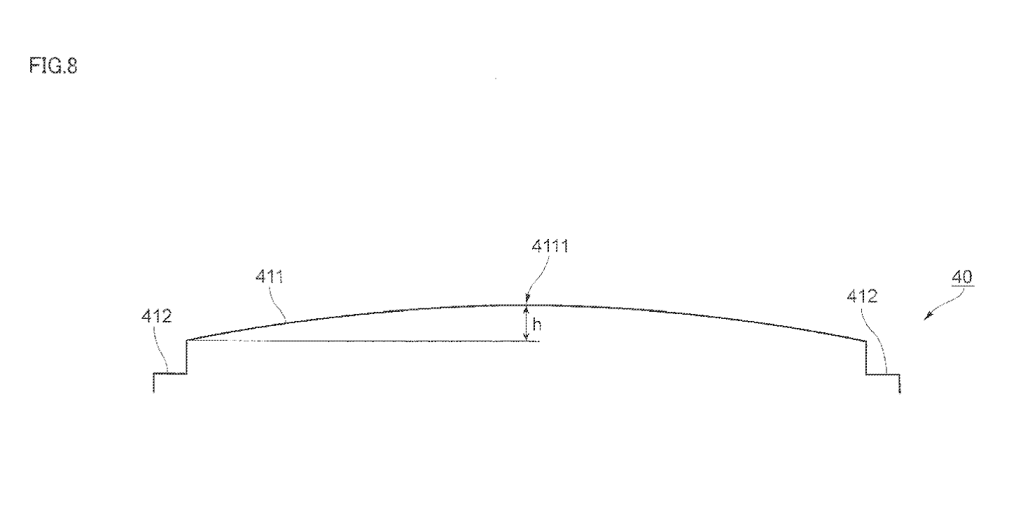

FIG. 8 is a diagram for illustrating an example of a configuration of the wafer carrying surface 411 in the carrying member 40. It should be noted that a cross section of the carrying member 40 shown in FIG. 8 corresponds to the VIIC-VIIC cross section in FIG. 3A; however, here, to help understanding of the present invention, projections and depressions in the wafer carrying surface 411 are exaggerated.

In the exemplary embodiment, the wafer carrying surface 411, which indicates substantially a circular shape as viewed from above, has an angle (convex-shaped) cross-sectional shape in which the cross section gradually becomes higher from the circumferential edge toward the center thereof. Consequently, distribution of contour lines in the wafer carrying surface 411 is substantially concentric. It should be noted that, in this description, the highest position in the wafer carrying surface 411 is referred to as a peak portion 4111, and the height of the peak portion 4111 with reference to the circumferential edge of the wafer carrying surface 411 is referred to as a wafer carrying surface height h.

Here, in the exemplary embodiment, wafer W of 4 inches (100 mm) is used, and accordingly, the wafer retainer 30 is configured to be able to carry the 4-inch wafer W. Consequently, the diameter of the wafer carrying surface 411 (except for the position corresponding to the orientation flat) in the carrying member 40 is 100 mm. Then, in the exemplary embodiment, whereas the diameter of the wafer carrying surface 411 is 100 mm, the wafer carrying surface height h is set at 17.5±7.5 μm at room temperature (25° C.). Moreover, the peak portion 4111 in the wafer carrying surface 411 is positioned within a radius of 20 mm from the center of the wafer carrying surface 411 (the center of the circle).

Then, in the exemplary embodiment, on the surface of the wafer carrying surface 411 (the coating layer of SiC) in the carrying member 40, lapping by polishing is applied. Accordingly, an arithmetic average roughness Ra in the wafer carrying surface 411 is set at not more than 0.5 μm, and more preferably, 0.3±0.1 μm (0.2 μm to 0.4 μm). It should be noted that, on the surface of the ring carrying surface 412 (the coating layer of SiC) in the carrying member 40, lapping, as on the wafer carrying surface 412, is not applied. Consequently, the ring carrying surface 412 has an arithmetic average roughness Ra larger than that of the wafer carrying surface 411.

Here, the wafer retainer 30 of the exemplary embodiment is configured by combining the carrying member 40 and the regulating member 50 as described above, and in the top surface 41 of the carrying member 40, the wafer carrying surface 411 is positioned at the highest portion. Accordingly, in comparison with a conventional wafer retainer configured by integrating the carrying member 40 and the regulating member 50, it is easier to form the convex surface in the wafer carrying surface 411 and polish the formed convex surface (apply lapping), and accuracy of surfaces is provided with ease.

### <Configuration of Laminated Semiconductor Wafer>

FIG. 9 is a cross-sectional view showing an example of a laminated semiconductor wafer SW produced by use of the above-described MOCVD device 1. It should be noted that the laminated semiconductor wafer SW shown in FIG. 9 becomes a starting material for producing, for example, a light emitting chip that emits blue light.

The laminated semiconductor wafer SW includes: a substrate 110; an intermediate layer 120 formed on the substrate 110; and a base layer 130, an n-type semiconductor layer 140, a light-emitting layer 150 and a p-type semiconductor layer 160 that are sequentially laminated on the intermediate layer 120.

Here, the n-type semiconductor layer 140 includes an n-type contact layer 140a provided on the base layer 130 side and an n-type cladding layer 140b provided on the light emitting layer 150 side. Moreover, the light emitting layer 150 has a multiple quantum well structure in which barrier layers 150a and well layers 150b are alternately laminated, and two barrier layers 150a sandwich a single well layer 150b. Further, the p-type semiconductor layer 160 includes a p-type cladding layer 160a provided on the light emitting layer 150 side and a p-type contact layer 160b provided as the uppermost layer.

It should be noted that, in the following description, the substrate 110, the intermediate layer 120 and the base layer 130 are collectively referred to as a lamination substrate 100, and the n-type semiconductor layer 140, the light emitting layer 150 and the p-type semiconductor layer 160 are collectively referred to as a compound semiconductor layer 170.

### (Substrate 110)

The substrate 110 is composed of a material different from a material of the group III nitride compound semiconductor, and group III nitride semiconductor crystals are epitaxially grown on the substrate 110. As the material constituting the substrate 110, for example, sapphire, carbonized silicon (silicon-carbide: SiC), silicon or the like can be used.

### (Intermediate Layer 120)

As described above, the substrate 110 is composed of a material different from a material of the group III nitride compound semiconductor. Accordingly, it is preferable to provide the intermediate layer 120 that performs a buffering function on the substrate 110 before the compound semiconductor layer 170 is formed by the MOCVD device 1 shown in FIG. 1. Especially, in terms of the buffering function, it is preferable that the intermediate layer 120 has a single crystal structure. In the case where the intermediate layer 120 having the single crystal structure is formed on the substrate 110, the buffering function of the intermediate layer 120 effectively works, and accordingly, the base layer 130 and the compound semiconductor layer 170 to be formed on the intermediate layer 120 become crystal films having excellent crystallinity.

The intermediate layer 120 preferably contains Al, and in particular, preferably contains AlN which is group III nitride.

### (Base Layer 130)

As a material used for the base layer 130, a group III nitride containing Ga (a GaN-based compound semiconductor) is used, and in particular, AlGaN or GaN can be preferably used. The thickness of the base layer 130 is not less than 0.1 μm, preferably not less than 0.5 μm, and more preferably not less than 1 μm.

### (N-Type Semiconductor Layer 140)

The n-type semiconductor layer 140 is configured with the n-type contact layer 140a and the n-type cladding layer 140b.

As the n-type contact layer 140a, similar to the base layer 130, a GaN-based compound semiconductor is used. Moreover, the gallium nitride-based compound semiconductors which constitute the base layer 130 and the n-type contact layer 140a have preferably the identical composition, and the total thickness of these layers is set in a range from 0.1 μm to 20 μm, preferably in a range from 0.5 μm to 15 μm, and more preferably in a range from 1 μm to 12 μm.

On the other hand, the n-type cladding layer 140b is capable of being formed by AlGaN, GaN, GaInN or the like. Moreover, hetero junction of these structures or a superlattice structure in which these structures are laminated plural times may also be employed. When GaInN is employed as the n-type cladding layer 140b, it is preferable to set the band gap thereof larger than that of GaInN in the light emitting layer 150. The thickness of the n-type cladding layer 140b is preferably in a range from 5 nm to 500 nm, and more preferably in a range from 5 nm to 100 nm.

### (Light Emitting Layer 150)

In the light emitting layer 150, the barrier layers 150a composed of a gallium nitride-based compound semiconductor and the well layers 150b composed of the gallium nitride-based compound semiconductor containing indium are alternately laminated in a repeated manner, and the barrier layers 150a are provided in such an order to face the n-type semiconductor layer 140 and the p-type semiconductor layer 160, respectively. In the exemplary embodiment, the light emitting layer 150 is configured so that six barrier layers 150a and five well layers 150b are alternately laminated in a repeated manner, and the barrier layers 150a are arranged as the uppermost and lowermost layers of the light emitting layer 150, and the well layers 150b are arranged between the barrier layers 150a.

As the barrier layer 150a, a gallium nitride-based compound semiconductor, such as Al_{c}Ga_{1-c}N (0≦c≦0.3), which has a larger band gap energy than that of the well layer 150b composed of the gallium nitride-based compound semiconductor containing indium, can be preferably used.

Moreover, for the well layer 150b, as the gallium nitride-based compound semiconductor containing indium, a gallium indium nitride such as Ga₁₋ₛInₛN (0<s<0.4) (hereinafter, sometimes referred to as “GaInN”) can be used.

The thickness of the entire light emitting layer 150 is not particularly limited; however, the thickness by which quantum effects can be obtained, that is, the critical thickness, is preferable. For example, the thickness of the light emitting layer 150 is preferably in a range from 1 nm to 500 nm, and more preferably, in a range in the neighborhood of 100 nm. Moreover, the thickness of the well layer 150b is not particularly limited; however, the thickness by which quantum effects can be obtained is preferable.

### (P-Type Semiconductor Layer 160)

The p-type semiconductor layer 160 is configured with the p-type cladding layer 160a and the p-type contact layer 160b. As the p-type cladding layer 160a, those composed of Al_{d}Ga_{1-d}N (0<d≦0.4) are preferably provided. The thickness of the p-type cladding layer 160a is preferably in a range from 1 nm to 400 nm, and more preferably in a range from 5 nm to 100 nm.

On the other hand, as the p-type contact layer 160b, a gallium nitride-based compound semiconductor layer containing AlₑGa₁₋ₑN (0≦e<0.5) is provided. The thickness of the p-type contact layer 160b is not particularly limited; however, it is preferably in a range from 10 nm to 500 nm, and more preferably in a range from 50 nm to 200 nm.

It should be noted that, in the MOCVD device 1 of the exemplary embodiment, a first lamination process, in which the intermediate layer 120 and the base layer 130 are laminated on the substrate 110 to obtain the lamination substrate 100, and a second lamination process, in which the compound semiconductor layer 170 containing the n-type semiconductor layer 140, the light emitting layer 150 and the p-type semiconductor layer 160 is laminated on the base layer 130 of the lamination substrate 100 to obtain the laminated semiconductor wafer SW, are carried out. For this reason, for example, in the first lamination process, the substrate 110 is the wafer W, whereas, for example, in the second lamination process, the lamination substrate 100 is the wafer W.

### <Method of Producing Laminated Semiconductor Wafer>

Here, description will be given of a method of producing the laminated semiconductor wafer SW by laminating the compound semiconductor layer 170 on the lamination substrate 100, as a specific example of the wafer W, by use of the MOCVD device 1.

First, the lamination substrate 100 is attached to the wafer retainer 30 configured by combining the carrying member 40 and the regulating member 50. At this time, the substrate 110 side of the lamination substrate 100 is carried on the wafer carrying surface 411 of the carrying member 40 in the wafer retainer 30, to thereby expose the base layer 130 in the lamination substrate 100 to the outside. In association with this, a circumferential surface (a side surface) of the lamination substrate 100 comes to face an inner wall surface of the regulating member 50 in the wafer retainer 30, and accordingly, the lamination substrate 100 is brought into a state of loosely fitting into the wafer retainer 30.

Next, the six wafer retainers 30, each of which retains the lamination substrate 100, are set on the support body 20 provided in the MOCVD device 1. To be described more specifically, in the MOCVD device 1, in a state where the lid portion 12 is opened with respect to the container portion 11, the six wafer retainers 30, each retaining the lamination substrate 100, are arranged at the respective recessed portions (six portions) provided in the support body 20 so that the base layer 130 in the lamination substrate 100 faces upwardly. At this time, the carried surface 421 of the bottom surface 42 in the carrying member 40 of each of the wafer retainers 30 comes to contact the bottom surface of each recessed portion provided in the support body 20. Thereafter, the lid portion 12 is closed with respect to the container portion 11, and by performing degassing to bring the lid portion 12 into intimate contact with the container portion 11, to thereby form the reaction chamber.

Subsequently, by rotating the support body 20 in the direction of arrow A via the shaft 21 and supplying nitride N₂ to each recessed portion provided in the support body 20 via the not-shown through hole, each wafer retainer 30 and the lamination substrate 100 retained by each wafer retainer 30 are rotated in the direction B on the support body 20 being rotated in the direction A. Moreover, supply of the carrier gas is started via the supply tube 13.

Further, current-passing to the heater portion 60 is started, and thereby the lamination substrate 100 retained by each wafer retainer 30 is heated via the support body 20 and each wafer retainer 30 to a set temperature (a first set temperature: in this specific example, 1090° C.) for epitaxially growing the n-type contact layer 140a. Then, in a state where the lamination substrate 100 is heated to the first set temperature, supply of the raw material gas for the n-type contact layer 140a is started via the supply tube 13.

Then, on the surface side of the base layer 130 in the lamination substrate 100, the raw material gas supplied from the outside reacts by the heat of the lamination substrate 100. As a result, the n-type contact layer 140a is epitaxially grown on the base layer 130.

When a predetermined time (a time required for obtaining an intended thickness of the n-type contact layer 140a) has passed, supply of the raw material gas for the n-type contact layer 140a through the supply tube 13 is halted. Consequently, lamination of the n-type contact layer 140a is completed.

Next, by changing the current-passing state (the current value) to the heater portion 60 as necessary, the lamination substrate 100 (here, including up to the n-type contact layer 140a, and hereinafter the same shall apply) retained by each wafer retainer 30 is heated via the support body 20 and each wafer retainer 30 to a set temperature (a second set temperature: in this specific example, 780° C.) for epitaxially growing the n-type cladding layer 140b. Then, in a state where the lamination substrate 100 is heated to the second set temperature, supply of the raw material gas for the n-type cladding layer 140b is started via the supply tube 13.

Then, on the surface side of the n-type contact layer 140a in the lamination substrate 100, the raw material gas supplied from the outside reacts by the heat of the lamination substrate 100. As a result, the n-type cladding layer 140b is epitaxially grown on the n-type contact layer 140a.

When a predetermined time (a time required for obtaining an intended thickness of the n-type cladding layer 140b) has passed, supply of the raw material gas for the n-type cladding layer 140b through the supply tube 13 is halted. Consequently, lamination of the n-type cladding layer 140b is completed.

Subsequently, by changing the current-passing state to the heater portion 60 as necessary, the lamination substrate 100 (here, including up to the n-type cladding layer 140b, and hereinafter the same shall apply) retained by each wafer retainer 30 is heated via the support body 20 and each wafer retainer 30 to a set temperature (a third set temperature: in this specific example, 800° C.) for epitaxially growing the barrier layer 150a. Then, in a state where the lamination substrate 100 is heated to the third set temperature, supply of the raw material gas for the barrier layer 150a is started via the supply tube 13.

Then, on the surface side of the n-type cladding layer 140b in the lamination substrate 100, the raw material gas supplied from the outside reacts by the heat of the lamination substrate 100. As a result, the first barrier layer 150a is epitaxially grown on the n-type cladding layer 140b.

When a predetermined time (a time required for obtaining an intended thickness of the barrier layer 150a) has passed, supply of the raw material gas for the barrier layer 150a through the supply tube 13 is halted. Consequently, lamination of the first barrier layer 150a is completed.

Further subsequently, by changing the current-passing state to the heater portion 60 as necessary, the lamination substrate 100 (here, including up to the first barrier layer 150a, and hereinafter the same shall apply) retained by each wafer retainer 30 is heated via the support body 20 and each wafer retainer 30 to a set temperature (a fourth set temperature: in this specific example, 800° C.) for epitaxially growing the well layer 150b. Then, in a state where the lamination substrate 100 is heated to the fourth set temperature, supply of the raw material gas for the well layer 150b is started via the supply tube 13.

Then, on the surface side of the first barrier layer 150a in the lamination substrate 100, the raw material gas supplied from the outside reacts by the heat of the lamination substrate 100. As a result, the first well layer 150b is epitaxially grown on the first barrier layer 150a.

When a predetermined time (a time required for obtaining an intended thickness of the well layer 150b) has passed, supply of the raw material gas for the well layer 150b through the supply tube 13 is halted. Consequently, lamination of the first well layer 150b is completed.

Thereafter, heating to the third set temperature and supply of the raw material gas for the barrier layer 150a and heating to the fourth set temperature and supply of the raw material gas for the well layer 150b are alternately repeated, to thereby obtain the light emitting layer 150 in which the barrier layers 150a and the well layers 150b are alternately laminated. It should be noted that the uppermost layer in the light emitting layer 150 is the last barrier layer 150a (in this specific example, the sixth barrier layer 150a).

Then, by changing the current-passing state to the heater portion 60 as necessary, the lamination substrate 100 (here, including up to the last barrier layer 150a, and hereinafter the same shall apply) retained by each wafer retainer 30 is heated via the support body 20 and each wafer retainer 30 to a set temperature (a fifth set temperature: in this specific example, 1090° C.) for epitaxially growing the p-type cladding layer 160a. Then, in a state where the lamination substrate 100 is heated to the fifth set temperature, supply of the raw material gas for the p-type cladding layer 160a is started via the supply tube 13.

Then, on the surface side of the last barrier layer 150a in the lamination substrate 100, the raw material gas supplied from the outside reacts by the heat of the lamination substrate 100. As a result, the p-type cladding layer 160a is epitaxially grown on the last barrier layer 150a.

When a predetermined time (a time required for obtaining an intended thickness of the p-type cladding layer 160a) has passed, supply of the raw material gas for the p-type cladding layer 160a through the supply tube 13 is halted. Consequently, lamination of the p-type cladding layer 160a is completed.

Thereafter, by changing the current-passing state to the heater portion 60 as necessary, the lamination substrate 100 (here, including up to the p-type cladding layer 160a, and hereinafter the same shall apply) retained by each wafer retainer 30 is heated via the support body 20 and each wafer retainer 30 to a set temperature (a sixth set temperature: in this specific example, 1090° C.) for epitaxially growing the p-type contact layer 160b. Then, in a state where the lamination substrate 100 is heated to the sixth set temperature, supply of the raw material gas for the p-type contact layer 160b is started via the supply tube 13.

Then, on the surface side of the p-type cladding layer 160a in the lamination substrate 100, the raw material gas supplied from the outside reacts by the heat of the lamination substrate 100. As a result, the p-type contact layer 160b is epitaxially grown on the p-type cladding layer 160a.

When a predetermined time (a time required for obtaining an intended thickness of the p-type contact layer 160b) has passed, supply of the raw material gas for the p-type contact layer 160b through the supply tube 13 is halted. Consequently, lamination of the p-type contact layer 160b is completed.

From above, the laminated semiconductor wafer SW shown in FIG. 9, which is configured by laminating the compound semiconductor layer 170 on the lamination substrate 100, is obtained.

Thereafter, the laminated semiconductor wafer SW obtained in this manner is divided after the electrodes or the like are formed, to provide the plural light emitting chips. At this time, in the plural light emitting chips obtained from a single laminated semiconductor wafer SW, it is preferable to reduce variations in the light emission wavelength among the light emitting chips as small as possible.

Here, the light emission wavelength of the light emitting chip is determined by the ratio of Ga and In in the well layers 150b (composed of GaInN) constituting the light emitting layer 150. Accordingly, in producing the laminated semiconductor wafer SW by use of the MOCVD device 1, it is important to suppress variations in composition in GaInN when the well layers 150b are epitaxially grown.

The variations in composition in GaInN of the well layers 150b are caused due to variations in temperature of the lamination substrate 100 in the epitaxial growth of the light emitting layer 150 (more specifically, the well layers 150b). To be described more specifically, when the well layers 150b are grown on the lamination substrate 100, the ratio of In in GaInN is apt to be reduced in a region of relatively high temperature compared to a region of relatively low temperature. It should be noted that, in the case where the ratio of In in GaInN is reduced (the ratio of Ga is increased), the light emission wavelength of the light emitting layer 150 becomes shorter, whereas, in the case where the ratio of In in GaInN is increased (the ratio of Ga is reduced), the light emission wavelength of the light emitting layer 150 becomes longer.

In laminating the light emitting layer 150, to cause the temperature distribution in the wafer W to be uniform, it is preferable that the temperature on the wafer carrying surface 411 in the carrying member 40 of the wafer retainer 30 is caused to be uniform, and thereafter, the contact state between a back surface of the wafer W (a surface facing the wafer carrying surface 411) and the wafer carrying surface 411 is caused to be uniform, and thermal conduction from the wafer retainer 30 to the wafer W is caused to be uniform. To cause the temperature on the wafer carrying surface 411 in the carrying member 40 to be uniform, it is important to suppress variations in heat radiation from the wafer carrying surface 411 by, for example, adding counter boring onto the bottom surface 42 side of the carrying member 40 (forming an outer facing surface 422 or an inner facing surface 423) and causing a thermal radiation rate of the wafer carrying surface 411 to be uniform. To cause the temperature of the wafer carrying surface 411 to be uniform and to cause the thermal conduction from the wafer carrying surface 411 to the wafer W to be uniform, it is important to cause the surface roughness (for example, an arithmetic average roughness Ra) to be uniform, and in the temperature for the growth of the light emitting layer 150 (in this specific example, 800° C.), to match the shapes of the back surface of the wafer W and the wafer carrying surface 411 in the carrying member 40 of the order of μm.

Here, in laminating the light emitting layer 150 on the wafer W, in which up to the n-type semiconductor layer 140 has been laminated, a film (the light emitting layer 150) having little defects with good quality tends to be obtained if the shape of the wafer W can be controlled to a state with substantially no warping (a near-flat state). However, since the wafer retainer 30 that retains the wafer W is to be heated mainly from the back surface side (the bottom surface side 42 in the carrying member 40), the temperature is apt to be higher on the bottom surface 42 than on the top surface 41 in the carrying member 40 (including the wafer carrying surface 411). Consequently, at the growth temperature of the light emitting layer 150, due to a difference in thermal expansion between both sides (the top surface 41 side and the bottom surface 42 side) of the carrying member 40, the carrying member 40 tends to be in a convex state toward the bottom surface 42 side compared to the state of room temperature.

In the conventional wafer retainer configured by integrating the carrying member 40 and the regulating member 50, since the surface to carry the wafer was positioned on the depth side as viewed from the ring, it was difficult to control an arithmetic average roughness Ra by polishing or the like, the value of the arithmetic average roughness Ra exceeded 1 μm, and variations thereof was large. Moreover, in the conventional wafer retainer, variations in the surface roughness on the surface to carry the wafer easily occurred by repeated use, and along with this, thermal radiation rate or contact thermal resistance became non-uniform, which was a cause of occurrence of variations in composition in the light emitting layer 150 (the well layers 150b) to be laminated.

Further, in the conventional wafer retainer, attempts to adjust the surface shape or surface roughness of the surface to carry the wafer were made in the state of being integrated with the ring; however, in the portions near the ring, it was impossible to use a large grindstone or the like because the ring had to be avoided, and therefore, it was extremely difficult to accurately control the surface shape (the convex state) and the surface roughness over the entire surface to carry the wafer, and as a result, a wafer retainer that was largely deviated from the intended surface shape or the surface roughness was used.

Therefore, in the exemplary embodiment, the shape of the carrying member 40 constituting the wafer retainer 30 was set to be convex on the top surface 41 side (on the wafer carrying surface 411 side) at room temperature. By setting the shape of the carrying member 40 in this manner, the surface shape of the wafer carrying surface 411 is in a state of substantially flat near the growth temperature of the light emitting layer 150, which can be close to the shape of the lamination substrate 100 near the growth temperature of the light emitting layer 150. As a result, near the growth temperature of the light emitting layer 150, in almost all region of the lamination substrate 100, it becomes possible to make a distance between the back surface of the lamination substrate 100 and the wafer carrying surface 411 in the carrying member 40 a predetermined value or less. Accordingly, it is possible to suppress variations in temperature of the lamination substrate 100 in the epitaxial growth of the compound semiconductor layer 170 containing the well layers 150b, to thereby make it possible to suppress variations in composition of GaInN in the well layers 150b. As a result, it is possible to suppress variations in light emission wavelength among the plural light emitting chips obtained by dividing the laminated semiconductor wafer SW.

Moreover, in the exemplary embodiment, the arithmetic average roughness Ra of the wafer carrying surface 411 in the carrying member 40 was set at not more than 0.5 μm. This makes it possible to suppress variations in heat radiated from the wafer carrying surface 411, namely, in-plane variations in heat supplied to the lamination substrate 100, and thereby variations in composition of GaInN in the well layers 150b can be suppressed.

Here, in the exemplary embodiment, in the carrying member 40 constituting the wafer retainer 30, the thickness of the carrying member 40 on the outer circumferential side and the inner circumferential side is made different from the thicknesses of other portions by forming the outer facing surface 422 and the inner facing surface 423 on the bottom surface 42 side. Then, provision of distribution in the thickness of the carrying member 40 contributes to suppression of the above-described variations in temperature of the lamination substrate 100.

Further, in the exemplary embodiment, the wafer retainer 30 that retains the lamination substrate 100 as the wafer W was configured with the carrying member 40 to carry the lamination substrate 100 and the regulating member 50 to surround the lamination substrate 100 carried on the carrying member 40 for regulating movement of the lamination substrate 100. In the case of epitaxially growing the compound semiconductor layer 170 on the lamination substrate 100, the wafer retainer 30 itself also comes to be deformed (subjected to thermal expansion) with being heated. Here, in the conventional wafer retainer configured by integrating a carrying portion to carry the lamination substrate 100 and a ring-like wall portion to surround the carried lamination substrate 100, when the carrying portion is to be deformed with being heated, the carrying portion is prevented from being deformed by the wall portion integrated with the carrying portion in some cases. In this case, even though a carrying surface of the wafer W in the carrying portion is, for example, formed in a convex state in which a center is higher than a circumferential edge at room temperature, when heat is applied, there is a possibility that the shape is deformed by the integrated wall portion and incapable of deforming to a flat shape. In contrast, in the exemplary embodiment, by configuring the wafer retainer 30 with the carrying member 40 and the regulating member 50, in the case where, for example, the carrying member 40 is to be deformed with being heated, the regulating member 50 rarely interferes with the deformation; accordingly, the shape of the wafer carrying surface 411 in the carrying member 40 easily transits from the convex state to the flat state when being heated. Consequently, this also suppresses variations in temperature of the lamination substrate 100 in the epitaxial growth of the compound semiconductor layer 170 containing the well layers 150b, and therefore, it becomes possible to suppress variations in composition of GaInN in the well layers 150b.

Moreover, since the wafer retainer 30 of the exemplary embodiment is configured by combining the carrying member 40 and the regulating member 50, for example, after producing the above-described laminated semiconductor wafer SW, it is possible to separate the laminated semiconductor wafer SW into the carrying member 40 and the regulating member 50 and clean each of them. Moreover, for example, after producing the above-described laminated semiconductor wafer SW, it is possible to separate the laminated semiconductor wafer SW into the carrying member 40 and the regulating member 50, clean the carrying member 40 to reuse, and replace the regulating member 50 with a new one.

Further, the carrying member 40 after cleaning and separating can be subjected to not only the cleaning but also reprocessing on the wafer carrying surface 411 thereof. At this time, on the top surface 41 of the carrying member 40, since the wafer carrying surface 411 is positioned at the highest portion as described above, it is easy to reform the convex surface on the wafer carrying surface 411 and re-polish (lapping process) the convex surface that has been formed.

It should be noted that, in the exemplary embodiment, the carrying member 40 and the regulating member 50 constituting the wafer retainer 30 were composed of different materials; however, the present invention is not limited thereto, and the carrying member 40 and the regulating member 50 may be composed of the same material.

Moreover, in the exemplary embodiment, description was given of a case where the laminated semiconductor wafer SW was obtained by epitaxially growing the group III nitride semiconductor layer on the substrate 110 made of sapphire as a specific example; however, the present invention is not limited thereto. For example, a compound semiconductor such as a group III-V compound semiconductor, a group II-VI compound semiconductor or a group IV-IV compound semiconductor may be laminated on the substrate 110.

Further, in the exemplary embodiment, description was given of a case where the substrate 110 and the compound semiconductor laminated on the substrate 110 were of different kinds as a specific example; however, the present invention is not limited thereto and may be applied to a case where the substrate 110 and the compound semiconductor laminated on the substrate 110 are of the same kinds.

### Example

Next, Examples according to the present invention will be described; however, the present invention is not limited thereto.

The inventors of the present invention carried out lamination of the compound semiconductor layer 170 on the lamination substrate 100 by use of the MOCVD device 1 shown in FIG. 1 or the like, and studied relation between the configuration of the wafer retainer 30 used at that time and photoluminescence property (PL wavelength distribution) in the obtained laminated semiconductor wafer SW.

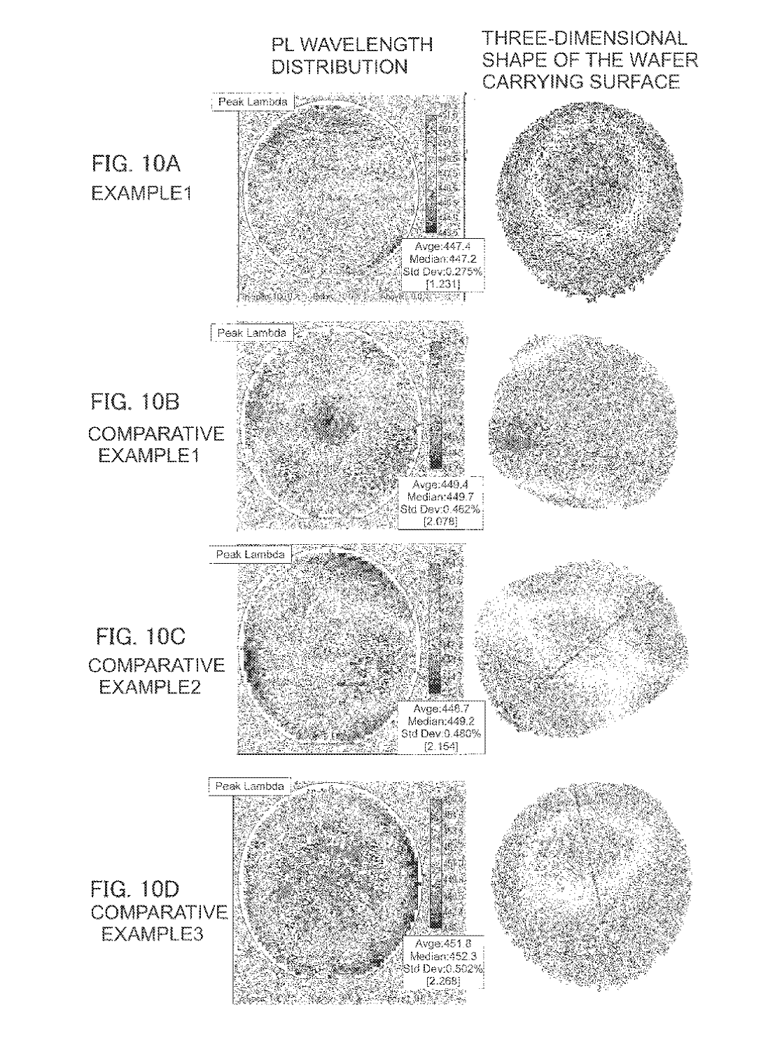

FIG. 10A to 10D are diagrams showing relation between a three-dimensional shape of the wafer carrying member 411 in the wafer retainer 30 and PL wavelength distribution in the obtained laminated semiconductor wafer SW in each of Example 1 and Comparative Examples 1 to 3.

Here, in Example 1, the wafer retainer 30 configured by combining the carrying member 40 and the regulating member 50 described in the exemplary embodiment (refer to FIGS. 3A, 3B to 8) was used. On the other hand, in Comparative Examples 1 and 2, the conventional wafer retainer 30 integrating the carrying portion and the regulating portion was used.

Moreover, as shown in FIG. 10A, in Example 1, the shape of the wafer carrying surface 411 at room temperature was a convex shape in which the center thereof was higher than the circumferential edge thereof. At this time, the wafer carrying surface height h of the wafer carrying surface 411 was set at 17.5 μm, and the arithmetic average roughness Ra of the wafer carrying surface 411 was set at 0.3 μm.

On the one hand, as shown in FIG. 10B, in Comparative Example 1, the shape of the wafer carrying surface 411 at room temperature was a deformed shape, which was neither in the flat state nor in the convex state. Here, in Comparative Example 1, as indicated by a straight line in the figure, there is a ridge portion extending from the center left to the lower right in the figure.

On the other hand, as shown in FIG. 10C, in Comparative Example 2, the shape of the wafer carrying surface 411 at room temperature was a deformed shape, which was neither in the flat state nor in the convex state, similar to Comparative Example 1. However, in Comparative Example 2, as indicated by a straight line in the figure, there is a ridge portion extending from the lower left to the upper right in the figure.

In contrast, as shown in FIG. 10D, in Comparative Example 3, the shape of the wafer carrying surface 411 at room temperature was a convex shape in which the center thereof was higher than the circumferential edge thereof, similar to Example 1. However, whereas the wafer carrying surface height h of the wafer carrying surface 411 was set at 17.5 μm, the arithmetic average roughness Ra of the wafer carrying surface 411 was set at 0.6 μm.

Next, obtained wavelength distribution will be described.

In Example 1, almost over the entire region of the laminated semiconductor wafer SW, variations in the PL wavelength is small.

In contrast, in Comparative Example 1, the PL wavelength is unevenly distributed so that the PL wavelength is longer in a region on the center side than in a region on the circumferential edge side of the laminated semiconductor wafer SW.

Moreover, in Comparative Example 2, the PL wavelength is unevenly distributed so that there are two regions on the circumferential edge side, where the PL wavelength is longer than in other regions.

Further, also in Comparative Example 3, the PL wavelength is unevenly distributed so that the PL wavelength is longer in a region on the center side than in a region on the circumferential edge side of the laminated semiconductor wafer SW.

In this manner, it can be learned that, by configuring the wafer retainer 30 with the carrying member 40 and the regulating member 50, forming the shape of the wafer carrying surface 411 of the carrying member 40 in a convex state that is raised from the edge toward the center, and making the wafer carrying surface 411 flat when microscopically viewed (setting the arithmetic average roughness Ra at not more than 0.5 μm), the laminated semiconductor wafer SW, in which the PL wavelength, and by extension, light emission wavelength having small variations, is available.

The foregoing description of the exemplary embodiment of the present invention has been provided for the purposes of illustration and description. It is not intended to be exhaustive or to limit the invention to the precise forms disclosed. Obviously, many modifications and variations will be apparent to practitioners skilled in the art. The exemplary embodiment was chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A device for producing a compound semiconductor that forms a compound semiconductor layer on a wafer by use of a chemical vapor deposition method, the device comprising:
a reaction container that contains the wafer inside thereof;
a wafer retainer that is provided in the reaction container and retains the wafer so that a surface of the wafer on which the compound semiconductor layer is formed faces upwardly;
a supply portion that supplies a raw material gas which is a raw material of the compound semiconductor layer from an outside to an inside of the reaction container; and
a heater portion that heats the wafer via the wafer retainer, wherein
the wafer retainer comprises:
a carrying member that carries the wafer; and
a regulating member that is carried on the carrying member and surrounds a circumferential surface of the wafer carried on the carrying member to regulate movement of the wafer, wherein
the carrying member includes a first carrying surface that carries the wafer and a second carrying surface that is provided around the first carrying surface and carries the regulating member, and
the first carrying surface is formed to protrude compared to the second carrying surface and has a surface shape in a convex state in which a center side is higher than a circumferential edge side, and an arithmetic average roughness Ra of the first carrying surface is not more than 0.5 μm.

2. The device for producing a compound semiconductor according to claim 1, further comprising:
a support body that is rotatably provided in the reaction container and supports the wafer retainer rotatably, wherein
the supply portion supplies the raw material gas from above or a lateral side of the support body.

3. The device for producing a compound semiconductor according to claim 1, wherein the heater portion heats the wafer in a range from not less than 700° C. to not more than 1200° C.

4. The device for producing a compound semiconductor according to claim 2, wherein the heater portion heats the wafer in a range from not less than 700° C. to not more than 1200° C.

5. A wafer retainer being used in a device for producing a compound semiconductor that forms a compound semiconductor layer on a wafer by use of a chemical vapor deposition method and retaining the wafer, the wafer retainer comprising:
a carrying member that carries the wafer; and
a regulating member that is carried on the carrying member and surrounds a circumferential surface of the wafer carried on the carrying member to regulate movement of the wafer, wherein
the carrying member includes a first carrying surface that carries the wafer and a second carrying surface that is provided around the first carrying surface and carries the regulating member, and
the first carrying surface is formed to protrude compared to the second carrying surface and has a surface shape in a convex state in which a center side is higher than a circumferential edge side, and an arithmetic average roughness Ra of the first carrying surface is not more than 0.5 μm.

6. The wafer retainer according to claim 5, wherein
the chemical vapor deposition method is a metal organic chemical vapor deposition method, and
the compound semiconductor layer is a group III nitride semiconductor layer.

7. The wafer retainer according to claim 5, wherein the wafer is configured with a substrate on which a compound semiconductor layer is formed in advance.

8. The wafer retainer according to claim 6, wherein the wafer is configured with a substrate on which a compound semiconductor layer is formed in advance.

9. The wafer retainer according to claim 5, wherein the carrying member is configured by forming a coating layer composed of SiC on a surface of a base composed of carbon, and the regulating member is composed of quartz.

10. The wafer retainer according to claim 6, wherein the carrying member is configured by forming a coating layer composed of SiC on a surface of a base composed of carbon, and the regulating member is composed of quartz.

11. The wafer retainer according to claim 7, wherein the carrying member is configured by forming a coating layer composed of SiC on a surface of a base composed of carbon, and the regulating member is composed of quartz.

12. The wafer retainer according to claim 8, wherein the carrying member is configured by forming a coating layer composed of SiC on a surface of a base composed of carbon, and the regulating member is composed of quartz.
